(19) United States
(12) Patent Application Publication
(10) Pub. No.: US 2025/0194052 A1
(43) Pub. Date: Jun. 12, 2025

(54) Electric Bicycle, and Control Unit for Use in Such a Bicycle

(71) Applicant: MA Micro Limited, London (GB)

(72) Inventors: Olivier Hébert, London (GB); Mao-Chieh Tang, London (GB); Chien I Chen, London (GB); Jen-Chung Liang, London (GB)

(21) Appl. No.: 18/846,331

(22) PCT Filed: Mar. 14, 2023
(86) PCT No.: PCT/NL2023/050131

§ 371 Date: Sep. 12, 2024

(30) Foreign Application Priority Data
Mar. 15, 2022 (NL) 2031285

(51) Int. Cl. H05K 7/20; B62M 6/45; B62M 6/80

(52) U.S. Cl. CPC H05K 7/2039; B62M 6/45; B62M 6/80

(57) ABSTRACT

The invention relates to an electric bicycle, including a bicycle frame, and one or more control units at least partially accommodated within said bicycle frame. The invention also relates to a control unit for use in such an electric bicycle according to the invention, wherein said control unit is at least partially accommodated within said bicycle frame.

### CROSS-REFERENCE TO RELATED APPLICATIONS

This application is the United States national phase of International Patent Application No. PCT/NL2023/050131 filed Mar. 14, 2023, and claims priority to The Netherlands Patent Application No. 2031285 filed Mar. 15, 2022, the disclosures of which are hereby incorporated by reference in their entireties.

### BACKGROUND OF THE INVENTION

### Field of the Invention

The invention relates to an electric bicycle, comprising a bicycle frame, and one or more control units and/or one or more bicycle devices at least partially accommodated within said bicycle frame. The invention also relates to a control unit and/or the bicycle device for use in such an electric bicycle according to the invention.

### Description of Related Art

Over the last 150 years, the bicycle has evolved to become one of the most efficient means of transportation in terms of conversion of energy into distance travelled. The efficiency of the bicycle has also been optimized to minimize the effort required by the rider. For instance, most modern bicycles include an efficient gear system to minimize rider effort. To further reduce the amount of human effort required to propel a bicycle, a variety of electric bicycles (e-bikes) have been introduced, wherein use is made of an electromotor as auxiliary power source to assist the manpowered pedalling process. These developments have resulted in faster bicycles, which facilitates bicycling at high speeds. Due to the presence of onboard electrical power, the electrical power is also more and more used to power further onboard electronic components, which has resulted in a significant increase of the complexity of the logistics to control these electronic components. Typically, this control is handled by a central control unit, also referred to main ECU (electronic control unit) and/or by at least one bicycle device, such as e.g., a (rechargeable) battery. Due to the increased number of electronic components to be controlled, and the increased complexity of a lot of electronic components, the design of the control unit also becomes more and more challenging and complicated. Although the complexity of the designs has increased, the size of the components of the control unit has continued to shrink with improvements in the ability to manufacture smaller electronic components and to pack more of these components in an ever smaller area. As electronic components of the control unit and/or the bicycle device become smaller and more densely packed on integrated boards and chips, designers and manufacturers now are faced with the challenge of how to dissipate the heat which is ohmicly or otherwise generated by these components, as it is well known that many electronic components, and especially power semiconductor components such as transistors and microprocessors, are more prone to failure or malfunction at high temperatures. Thus, the ability to dissipate heat often is a limiting factor on the performance of the component.

### SUMMARY OF THE INVENTION

It is a first object of the invention to provide an electric bicycle with an improved control unit and/or bicycle device.

It is a second object of the invention to provide an electric bicycle with a control unit and/or a bicycle device having improved heat dissipating properties.

At least one of these objects can be met by providing an electric bicycle, comprising:
a bicycle frame, and
at least one control unit and/or at least one bicycle device at least partially accommodated within said bicycle frame, wherein said control unit and/or said bicycle device comprises:
   at least one heat generating component, and
   at least one heat sink thermally co-acting with said at least one heat generating component configured to dissipate heat away from said heat generating component,
      wherein said at least one heat sink connects, preferably thermally, directly or indirectly, to a side, preferably an inner side, of a wall of said bicycle frame such that heat originating from said at least one heat generating component is dissipated at least partially via said at least one heat sink, directly or indirectly, into said wall of said bicycle frame.

A main advantage of the invention is that the control unit and/or the bicycle device uses the bicycle frame to dissipate heat energy into, and hence to release heat energy, which leads to a cooling, in particular a passive cooling, of the control unit and/or the bicycle device. This will be in favour of the durability and reliability of the control unit, and hence of the lifetime of the control unit and/or the bicycle device. This cooling effect is typically a passive cooling effect, wherein heat is transferred from material to material. It is nevertheless imaginable that an air flow is led through the bicycle frame to additionally realize an active cooling effect. This air flow can be a forced air flow, realized by means of at least one fan, or can be a natural air flow created during riding the bicycle. In particular in this latter case, the bicycle frame may be designed to allow the presence of such an air flow, for example by applying at least one air inlet and at least one air outlet in the bicycle frame, located at opposing sides of the control unit and/or the bicycle device. However, it is often preferred to omit such air inlets and outlets in order to keep the bicycle frame as watertight as possible during normal operation. It is imaginable that the bicycle device may be at least partially formed by at least one battery, preferably a rechargeable battery, more preferably a removable rechargeable battery, and/or a battery pack, and/or a power distribution unit (PDU), and/or a charging port, and/or a service port.

Since the bicycle frame is used for cooling the control unit and/or the bicycle device, wherein the bicycle frame will normally dissipate absorbed heat to the surrounding atmosphere, both the heat transfer surface (at least partially defined by said bicycle frame, of at least a part thereof), and the heat dissipation capacity to release heat to the atmosphere can be improved significantly.

For such passive cooling, physical contact between the control unit and/or the bicycle device, in particular at or near the heat sink(s), and the (inner side of the) sidewall is preferred to provide an (intensive) thermally conductive pathway between the control unit and/or the bicycle device and the bicycle frame. Since, said wall of said bicycle frame is preferably configured to act as heat absorption surface and/or as heat transfer surface, it is preferred that said wall, and/or said bicycle frame as such, is at least partially composed of conductive material, preferably thermally conductive material, such as metal and/or carbon.

Preferably, said control unit and/or the bicycle device comprises at least one thermally conductive interface, in particular a thermally conductive pad, attached, preferably adhered, directly or indirectly, to at least one heat sink, and interposed in between at least a part of said heat sink and said bicycle frame wall to provide a thermally conductive pathway therebetween. It is often preferred that the control unit and/or the bicycle device comprises a plurality of thermally conductive interfaces, such as pads, stickers, coatings, films, or other layers. The thermally conductive interface may be arranged side-by-side to increase the total heat transfer interface surface and/or may be stacked on top of each other which may be favourable in order to fill possible spaces between the heat sink and the bicycle frame in a relatively efficient manner. Preferably, at least one thermally conductive interface directly connects, preferably under bias, to the bicycle frame wall. Preferably, at least one thermally conductive interface is clamped in between the bicycle frame and the heat sink. Preferably, at least one thermally conductive interface is at least partially composed of a compressible material. Such a material is configured to adapted to the shape of both the heat sink and the bicycle frame in order to ensure an intensive and constant physical contact between the control unit and/or the bicycle device and the bicycle frame. Preferably, at least one thermally conductive interface is at least partially composed of at least one polymer, such as a urethane, preferably an elastomer, such as silicone rubber. Optionally, the polymer is admixed with at least one binder material, such as at least one filler chosen from the group consisting of: aluminium oxide, magnesium oxide, zinc oxide, boron nitride, and aluminium nitride.

Preferably, a distant side of the thermally conductive interface, facing away from the at least one heat sink, has a substantially smooth surface. Such a smooth surface (flat surface or unprofiled surface) allows said distant side of said thermally conductive interface to be in substantially continuous physical contact with the inner side of said bicycle frame wall. This latter ensures a desired intensive heat dissipation to the frame. A corrugated or otherwise profiled distant side of the thermally conductive interface will lead to an interface with locally increased thickness which will affect the heat dissipation to the frame, and moreover, leads to formation of cavities (air pockets) in between the corrugations and/or in between the profiled distant side and the frame, which leads to a discontinuous heat transfer surface which is normally less preferred. The same applies to the proximal side of the thermally conductive interface, facing towards from the at least one heat sink, which preferably has a substantially smooth surface. This allows a substantially continuous physical contact with heat generating component, which will be in favour of the heat dissipation process.

In a preferred embodiment, said control unit and/or said bicycle device comprises a plurality of thermally conductive interfaces, in particular thermally conductive pads, attached, preferably adhered, directly or indirectly, to at least one heat sink, and interposed in between at least a part of said heat sink and said bicycle frame wall to provide a thermally conductive pathway therebetween. Although it is imaginable that a plurality of thermally conductive interfaces is attacked on top of each other, as to form a laminate of multiple layers, preferably at least two, more preferably all, thermally conductive interfaces are positioned adjacent (side-by-side), optionally at a distance, from each other. Preferably, the plurality of thermally conductive interfaces are arranged in a linear array or matrix array, and wherein at least two of the plurality of thermally conductive interfaces are preferably arranged at a distance from each other. Such a distance may be a functional distance as will be explained below. Preferably, at least one heat sink is fastened to said at least one heat generating component by at least one mechanical fastening element, such as a screw, rivet, or bolt. This secure a durable and tight connection between the heat sink and the heat generating component, wherein the heat sink and the heat generating component are preferably pull towards each other by means of the one or more fastening elements, which is (also) in favour of realizing a good heat dissipation. Preferably, the at least one screw (or rivet or bolt) used to fasten said at least one heat sink to said at least one heat generating component, comprises a screw head (or rivet head or bolt heat), wherein said screw head (or rivet head or bolt heat) engages a side of the heat sink facing away of the heat generating component. In this way, said head is exposed and hence accessible during assembling and disassembling (e.g. in case of maintenance). In order to prevent the screw head(s) (or rivet head(s) or bolt head(s)) to protrude, which would or could affect the heat dissipation process, at least one head is preferably accommodated in a recessed portion of the heat sink. Preferably, each (screw, rivet, or bolt) head is positioned at a distance from the frame in installed condition to prevent that the head and the frame will damage each other. Preferably, at least two of the plurality of thermally conductive interfaces are arranged at a distance from each other, such that the screw head of the at least one screw is left uncovered, and preferably situated in between two adjacent thermally conductive interfaces. In this manner, the head(s) remain(s) accessible for (dis) assembling the heat sink and the heat generating component, and does not require removal of the thermally conductive interface(s) from the heat sink in case the heat sink has to be removed from the heat generating component (e.g. for maintenance reasons).

Preferably, the length of the heat sink is larger, preferably at least two times larger, than the length of an individual thermally conductive interface. This allows the application of on or more uncovered heat sink portions e.g. for mechanically fastening the heat sink to the at least one heat generating component. Preferably, at least 75%, more preferably at least 80%, at least 85%, at least 90%, or at least 95% of the heat sink surface facing towards the frame is covered with one or more thermally conductive pads to secure an intensive and sufficiently large heat dissipation from the heat sink, via the thermally conductive interface(s), to the bicycle frame.

Preferably, at least one thermally conductive interface is at least partially composed of an electrically insulating material (dielectric material). This latter will prevent short circuiting between the control unit and/or the bicycle device and the bicycle frame, which is in favour of the safety of the bicycle and the durability and reliability of the control unit and/or the bicycle device. This property can, for example, be realized by at least partially composing at least one thermally conductive pad by a metal oxide, such as alumina (Al₂O₃), filled elastomer, such as silicone rubber, which exhibits an unexpected convergence of a relatively high thermal conductivity (preferably larger than 0.75 W/m/K) and a relatively low electrical conductivity. In an alternative embodiment, the thermally conductive interface is electrically conductive, wherein the interface may be enriched with electrically conductive particles, such as carbon and/or graphite particles, and/or such as electrically conductive flakes, and/or chips, and/or platelets, and/or fibers, and/or spheres, etcetera. The particles are typically dispersed in the polymer.

In a preferred embodiment, at least one thermally conductive interface is at least partially composed of at least one thermoplastic polyurethane, preferably a polyether-based thermoplastic polyurethane. In this embodiment, the polyether group represents the “soft” or “flexible” segment.

Preferably, the thermal conductivity of the thermally conductive interface increases as pressure on the thermally conductive interface increases. Hence, a more biased, and hence more intensive, contact between said interface and the bicycle frame leads to an improved heat dissipation. In particular in case the thermally conductive interface is at least partially foamed, and in case such foamed interface is at least partially compressed, such an increase in thermal conductivity is typically realised.

As indicated above, at least one thermally conductive interface preferably has a thermal conductivity of at least about 0.75 W/m/K, preferably at least 0.85 W/m/K, more preferably at least 1.00 W/m/K. Such values are typically sufficient to dissipate sufficient heat energy per second (or other time unit) into the bicycle frame to ensure sufficient cooling of the control unit and/or the bicycle device.

It is preferable that at least one thermally conductive interface is adhered onto the heat sink by using a, preferably thermally conductive, adhesive and/or by using a, preferably thermally conductive, paste. Preferably, at least one thermally conductive interface comprises a first surface, composed of a first pressure sensitive adhesive (PSA), bonded to the heat sink, and an opposing second surface, composed of a second pressure sensitive adhesive (PSA), bonded to the inner surface of the wall of the bicycle frame. A PSA is a type of nonreactive adhesive which forms a bond when pressure is applied to bond the adhesive with a surface. No solvent, water, or heat is needed to activate the adhesive. Preferably, the first PSA and/or second PSA comprises a silicone pressure sensitive adhesive component optionally blended with a first thermally-conductive filler, and/or wherein said first PSA and/or second PSA comprises a blend of an acrylic pressure sensitive adhesive component and a second thermally-conductive filler. Preferably, said first PSA comprises between 0% and about 15% by weight of said first thermally-conductive filler, and wherein said second PSA comprises between about 15% and about 85% by weight of said second thermally conductive filler. It is imaginable that both the first PSA and the second PSA have the same composition. Depending upon the formulation, the respective acrylic and/or silicone-based PSA components may form a binder into which the thermally-conductive filler is dispersed. The filler generally is included within the binder in a proportion sufficient to provide the thermal conductivity desired for the heat transfer from the control unit and/or the bicycle device to the bicycle frame. That is, the filler may be of any general shape including spherical, flake, platelet, irregular, or fibrous, such as chopped or milled fibers, but preferably will be a powder or other particulate to assure uniform dispersal and homogeneous mechanical and thermal properties. Preferably, said first and said second thermally-conductive filler are selected from the group consisting of: boron nitride, titanium diboride, aluminium oxide, aluminium nitride, magnesium oxide, zinc oxide, silicon carbide, beryllium oxide, antimony oxide, and mixtures thereof. Such fillers characteristically exhibit a thermal conductivity of about 25-50 W/m/K. Optionally, additional fillers and additives may be included, such as conventional wetting, opacifying, chain extending oils, or anti-foaming agents, tackifiers, pigments, lubricants, stabilizers, flame retardants such, and antioxidants.

In a preferred embodiment, at least one thermally conductive interface comprises a phase change material (PCM), wherein said PCM preferably comprises a mixture of at least one polymeric component and at least one thermally conductive filler, wherein, more preferably, said filler is chosen from among boron nitride, titanium diboride, aluminium nitride, silicon carbide, graphite, metals, metals oxide, and mixtures thereof, and wherein, preferably, the polymeric component comprises one or more resins, one or more waxes, or a blend of one or more waxes and one or more resins. A PCM is configured to undergo a phase change between a (semi-) solid material and (semi-) liquid material within a specific operating range, dependent on the PCM composition. Typically, the PCM is at least partially composed of at least one salt, such as NaCl and/or Na₂SO₄, in particular NaCl·Na₂SO₄·10H₂O. Alternatively, the PCM is at least partially composed of at least one organic PCM, in particular paraffin, such as paraffin 17-carbons and/or paraffin 18-carbons. The PCM is typically encapsulated in at least one closed housing to prevent leakage of liquified PCM. For example, a PCM may be used to that is semi-liquid or solid at normal room temperature, i.e., about 25° C., but liquify or soften at elevated temperatures within the operating temperature range of the electronic component. During this phase transition of the PCM a relatively large amount of heat energy is absorbed as latent heat in the PCM.

Preferably, the heat sink comprises at least one thermally conductive block or strip covering at least a part of the at least one heat generating component, wherein said block or strip is preferably at least partially composed of metal, such as aluminium. Preferably, the control unit and/or the bicycle device comprises an outer casing. Preferably, at least a part of said heat sink is left uncovered by the outer casing. To this end, the outer casing is preferably provided with one or more openings to accommodate one or more outwardly protruding portions of the heat sink. The heat sink preferably comprises a sealing element, in particular a sealing ring, to seal a space, in particular a circumferential space, in between said outer casing and said heat sink. A suitable material of such a sealing element is for example an elastomer, such as silicone rubber.

Preferably, the control unit and/or the bicycle device is as such substantially watertight and/or water resistant. In this manner, water or moisture which would be present within the bicycle frame will not affect the control unit and/or the bicycle device. Typically, and preferably, a part of the control unit and/or the bicycle device, more preferably a side of the control unit and/or the bicycle device facing away from the heat sink, is at least partially left uncovered by the bicycle frame. This not only facilitates maintenance to the control unit and/or the bicycle device, but also allows exposure of one or more optional antennas of the control unit and/or the bicycle device which will be in favour of the antenna performance. Preferably, the control unit and/or the bicycle device is mounted to the bicycle frame by means of at least one fastening element, such as a screw.

Preferably, the bicycle frame comprises a top tube, wherein the control unit and/or the bicycle device is mounted to said top tube and at least partially accommodated within said top tube. More preferably, a lower side of the top tube is provided with an access opening for inserting the control unit and/or the bicycle device into the top tube and/or for removing the control unit and/or the bicycle device from the top tube. The control unit and/or the bicycle device may be considered as cartridge. Preferably, the heat sink is configured to dissipate heat originating from said at least one heat generating component to an upper section of the inner side of the wall of the top tube.

Preferably, the control unit and/or the bicycle device comprises at least one printed circuit board (PCB), and wherein at least one heat generating component, and typically a plurality of heat generating components, is mounted onto said PCB. Preferably, said control unit forms a main ECU (electronic control unit or main controller and/or the bicycle device). It is, however, also imaginable that the control unit is an alternative control unit and/or the bicycle device, for example an auxiliary control unit and/or a power control unit. It is imaginable that the bicycle comprises a plurality of control units and/or bicycle devices which are at least partially accommodated in the bicycle frame in such a way that the bicycle frame will be used a heat transfer component. At least one heat generating component is preferably chosen from the group consisting of: a capacitor, a battery, a connector, a semiconductor chip, a processor, and a metal-oxide-silicon field effect transistor (MOSFET).

The bicycle may further comprise foot pedals, wherein said pedals are, directly or indirectly, connected to a crank set of the bicycle for propelling the bicycle. In particular, the bicycle is a pedal operable electric bicycle. Moreover, the bicycle comprises preferably at least one electromotor to drive at least one wheel of the bicycle. It is preferred that the bicycle comprises a pedal-operated manpower driven system and an electromotor driven system in parallel to each other, wherein at least one bicycle control unit is configured to control the output of the electromotor driven in response to a pedal depressing force of the manpower driven system.

The invention also relates to a control unit and/or a bicycle device for use in a bicycle according to the invention, wherein the control unit and/or the bicycle device comprises:
at least one heat generating component, and
at least one heat sink configured to thermally co-act with said at least one heat generating component configured to dissipate heat away from said heat generating component,
   wherein said at least one heat sink is configured to connect, directly or indirectly, to a side, preferably an inner side, of a wall of said bicycle frame such that heat originating from said at least one heat generating component will be dissipated via said at least one heat sink at least partially into said wall of said bicycle frame. Advantages and embodiments of the control unit and/or the bicycle device have been described throughout this document.

Preferred embodiments of the invention are described in the non-limitative set of embodiments presented below:
1. Electric bicycle, comprising:
   a bicycle frame, and
   at least one control unit and/or at least one bicycle device at least partially accommodated within said bicycle frame, wherein said control unit and/or said bicycle device comprises:
      at least one heat generating component, and
      at least one heat sink thermally co-acting with said at least one heat generating component configured to dissipate heat away from said heat generating component, wherein said at least one heat sink connects, directly or indirectly, to an inner side of a wall of said bicycle frame such that heat originating from said at least one heat generating component is dissipated at least partially via said at least one heat sink into said wall of said bicycle frame.
2. Electric bicycle according to embodiment 1, wherein said wall of said bicycle frame is configured to act as heat absorption surface and/or as heat transfer surface.
3. Electric bicycle according to embodiment 1 or 2, wherein said wall of said bicycle frame is at least partially composed of conductive material, such as metal and/or carbon.
4. Electric bicycle according to embodiment 3, wherein the bicycle frame is at least partially, and preferably entirely, composed of a conductive material, such as metal and/or carbon.
5. Electric bicycle according to any of the preceding embodiments, wherein said control unit and/or said bicycle device comprises at least one thermally conductive interface, in particular a thermally conductive pad, attached, preferably adhered, directly or indirectly, to at least one heat sink, and interposed in between at least a part of said heat sink and said bicycle frame wall to provide a thermally conductive pathway therebetween.
6. Electric bicycle according to embodiment 5, wherein at least one thermally conductive interface directly connects to the bicycle frame wall.
7. Electric bicycle according to embodiment 5 or 6, wherein at least one thermally conductive interface is at least partially composed of a compressible material.
8. Electric bicycle according to any of embodiments 5-7, wherein at least one thermally conductive interface is at least partially composed of at least one polymer, preferably an elastomer, such as silicone rubber.
9. Electric bicycle according to embodiment 8, wherein at least one filler, such as alumina (Al₂O₃) and/or graphite and/or carbon, is dispersed, preferably as particles, in particular fibers, in the polymer.
10. Electric bicycle according to embodiment 8 or 9, wherein at least one thermally conductive interface is at least partially composed of at least one thermoplastic polyurethane, preferably a polyether-based thermoplastic polyurethane.
11. Electric bicycle according to any of embodiments 5-10, wherein the thermally conductive interface is an electrically insulating, thermally conductive interface.
12. Electric bicycle according to any of embodiments 5-11, wherein the thermal conductivity of the thermally conductive interface increases as pressure on the thermally conductive interface increases.
13. Electric bicycle according to any of embodiments 5-12, wherein at least one thermally conductive interface has a thermal conductivity of at least about 0.75 W/m/K.
14. Electric bicycle according to any of embodiments 5-13, wherein at least one thermally conductive interface comprises a first surface, composed of a first pressure sensitive adhesive (PSA), bonded to the heat sink, and an opposing second surface, composed of a second pressure sensitive adhesive (PSA), bonded to the inner surface of the wall of the bicycle frame.
15. Electric bicycle according to embodiment 14, wherein the first PSA and/or second PSA comprises a silicone pressure sensitive adhesive component optionally blended with a first thermally-conductive filler, and/or wherein said first PSA and/or second PSA comprises a blend of an acrylic pressure sensitive adhesive component and a second thermally-conductive filler.
16. Electric bicycle according to embodiment 15, wherein said first PSA comprises between 0% and about 15% by weight of said first thermally-conductive filler, and wherein said second PSA comprises between about 15% and about 85% by weight of said second thermally conductive filler.
17. Electric bicycle according to embodiment 16, wherein said first and said second thermally-conductive filler are selected from the group consisting of: boron nitride, titanium diboride, aluminium oxide, aluminium nitride, magnesium oxide, zinc oxide, silicon carbide, beryllium oxide, antimony oxide, and mixtures thereof.
18. Electric bicycle according to any of embodiments 5-17, wherein at least one thermally conductive interface comprises a phase change material (PCM), wherein said PCM preferably comprises a mixture of at least one polymeric component and at least one thermally conductive filler, wherein, more preferably, said filler is chosen from among boron nitride, titanium diboride, aluminium nitride, silicon carbide, graphite, metals, metals oxide, and mixtures thereof, and wherein, preferably, the polymeric component comprises one or more resins, one or more waxes, or a blend of one or more waxes and one or more resins.
19. Electric bicycle according to any of the preceding embodiments, wherein the heat sink comprises a thermally conductive block or strip covering at least a part of the at least one heat generating component, wherein said block or strip is preferably at least partially composed of metal, such as aluminium.
20. Electric bicycle according to any of the preceding embodiments, wherein the control unit and/or said bicycle device comprises an outer casing, and wherein the heat sink comprises a sealing element, in particular a sealing ring, to seal a space, in particular a circumferential space, in between said outer casing and said heat sink.
21. Electric bicycle according to embodiment 20, wherein the outer casing is provided with one or more openings to accommodate one or more outwardly protruding portions of the heat sink.
22. Electric bicycle according to any of the preceding embodiments, wherein the control unit and/or the bicycle device is substantially watertight.
23. Electric bicycle according to any of the preceding embodiments, wherein the control unit and/or the bicycle device is mounted to the bicycle frame by means of at least one fastening element, such as a screw.
24. Electric bicycle according to any of the preceding embodiments, wherein the bicycle frame comprises a top tube, wherein the control unit is mounted to said top tube and at least partially accommodated within said top tube.
25. Electric bicycle according to embodiment 24, wherein a lower side of the top tube is provided with an access opening for inserting the control unit into the top tube and for removing the control unit from the top tube.
26. Electric bicycle according to embodiment 24 or 25, wherein the heat sink is configured to dissipate heat originating from said at least one heat generating component to an upper section of the inner side of the wall of the top tube.
27. Electric bicycle according to any of the preceding embodiments, wherein the control unit and/or the bicycle device comprises at least one printed circuit board (PCB), and wherein at least one heat generating component is mounted onto said PCB.
28. Electric bicycle according to any of the preceding embodiments, wherein at least one control unit forms a main ECU (electronic control unit).
29. Electric bicycle according to any of the preceding embodiments, wherein at least one heat generating component is chosen from the group consisting of: a capacitor, a battery, a connector, a semiconductor chip, a processor, and a metal-oxide-silicon field effect transistor (MOSFET).
30. Bicycle according to any of the preceding embodiments, wherein the bicycle comprises foot pedals, wherein said pedals are, directly or indirectly, connected to a crank set of the bicycle for propelling the bicycle.
31. Electric bicycle according to any of the preceding embodiments, wherein the bicycle is a pedal operable electric bicycle.
32. Electric bicycle according to any of the preceding embodiments, wherein the bicycle comprises at least one electromotor to drive at least one wheel of the bicycle.
33. Electric bicycle according to any of the preceding embodiments, wherein the bicycle comprises a pedal-operated manpower driven system and an electromotor driven system in parallel to each other, wherein at least one bicycle control unit is configured to control the output of the electromotor driven in response to a pedal depressing force of the manpower driven system.
34. Electric bicycle according to any of the preceding embodiments, wherein said control unit and/or said bicycle device comprises a plurality of thermally conductive interfaces, in particular thermally conductive pads, attached, preferably adhered, directly or indirectly, to at least one heat sink, and interposed in between at least a part of said heat sink and said bicycle frame wall to provide a thermally conductive pathway therebetween.
35. Electric bicycle according to embodiment 34, wherein the plurality of thermally conductive interfaces are arranged in a linear array or matrix array, and wherein at least two of the plurality of thermally conductive interfaces are preferably arranged at a distance from each other.
36. Electric bicycle according to any of the preceding embodiments, wherein at least one heat sink is fastened to said at least one heat generating component by at least one mechanical fastening element, such as a screw.
37. Electric bicycle according to embodiment 36, wherein the at least one screw used to fasten said at least one heat sink to said at least one heat generating component, comprises a screw head, wherein said screw head engages a side of the heat sink facing away of the heat generating component.
38. Electric bicycle according to embodiment 37, wherein the screw head of said at least one screw is accommodated in a recessed portion of the heat sink.
39. Electric bicycle according to embodiment 36 and embodiment 37 or 38, wherein at least two of the plurality of thermally conductive interfaces are arranged at a distance from each other, such that the screw head of the at least one screw is left uncovered.
40. Electric bicycle according to any of the preceding embodiments, wherein the length of the heat sink is larger, preferably at least two times larger, than the length of an individual thermally conductive interface.
41. Control unit and/or bicycle device for use in a bicycle according to any of the preceding embodiments, wherein the control unit and/or the bicycle device comprises:
   at least one heat generating component, and
   at least one heat sink configured to thermally co-act with said at least one heat generating component configured to dissipate heat away from said heat generating component,
      wherein said at least one heat sink is configured to connect, directly or indirectly, to an inner side of a wall of said bicycle frame such that heat originating from said at least one heat generating component will be dissipated via said at least one heat sink into said wall of said bicycle frame.

### BRIEF DESCRIPTION OF THE DRAWINGS

The terms Fig., Figs., Figure, and Figures are used interchangeably in the specification to refer to the corresponding figures in the drawings.

The present invention will hereinafter be further elucidated based on the following non-limitative drawings, wherein:

FIG. 1 shows a perspective view of an assembly of a top tube of an electric bicycle, and a control unit mounted to said tube,

FIG. 2 shows a perspective longitudinal cross-sectional view of the assembly according to FIG. 1,

FIG. 3 shows a perspective view of the control unit according to FIGS. 1 and 2,

FIG. 4 shows a perspective cut-away view of the control unit according to the previous figures,

FIG. 5 shows another cross-sectional view of the control unit according to the previous figures, and

FIG. 6 shows a schematic overview of a bicycle according to the invention comprises the assembly as shown in FIG. 1.

### DESCRIPTION OF THE INVENTION

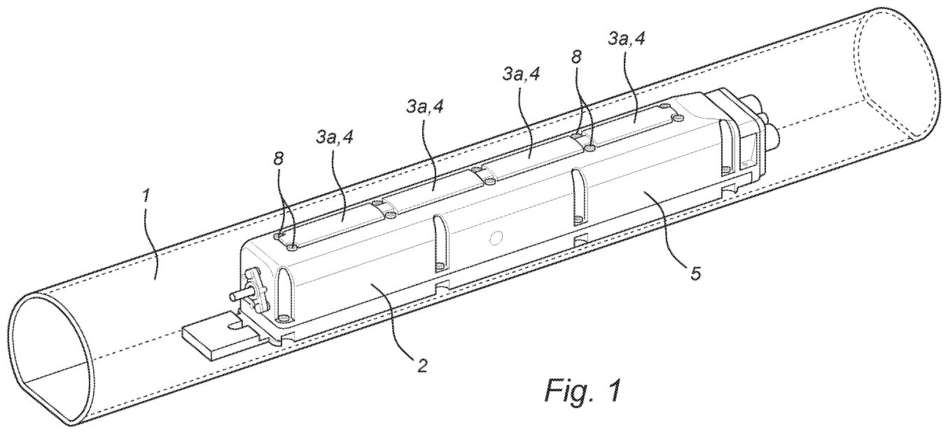

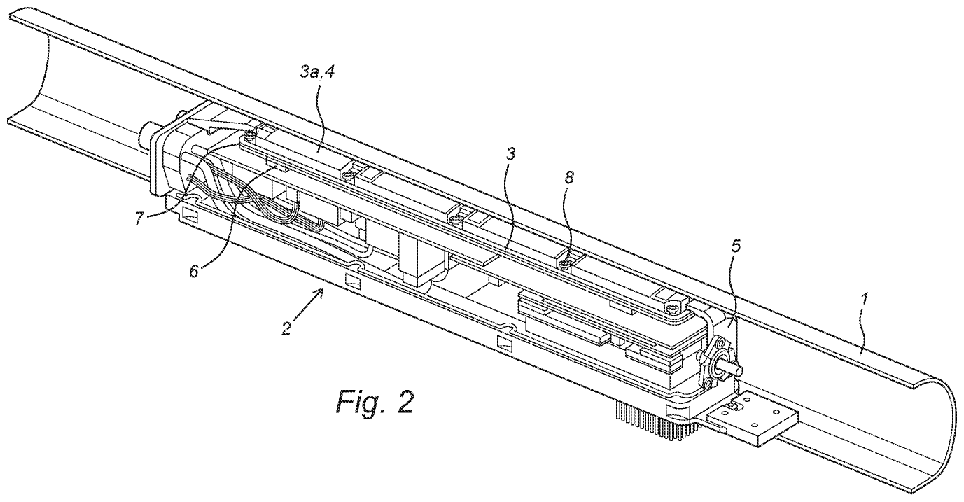

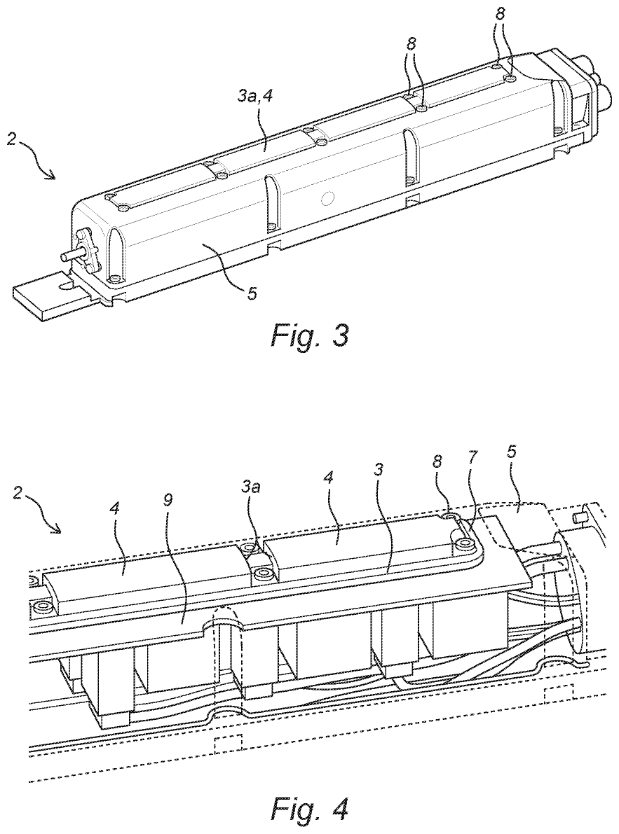

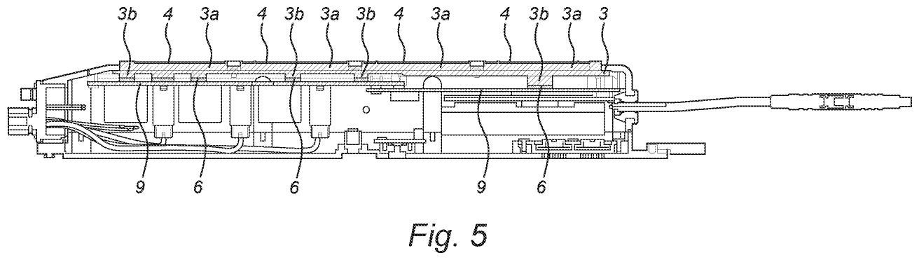

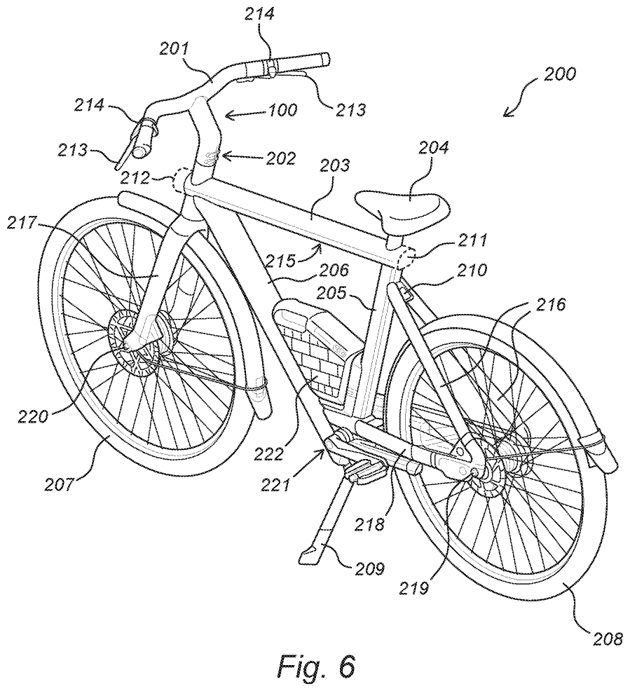

FIGS. 1 and 2 show a perspective view of an assembly of a top tube 1 of an electric bicycle, and a control unit 2 mounted to said tube 1. The top tube 1 makes part of a bicycle frame (see FIG. 6). The control unit 2 is mounted as cartridge to said top tube 1 and substantially accommodated within said top tube 1. The control unit 2 is fixated to the top tube 1 by means of one or more screws. The control unit 2 may be formed by a main controller (main ECU). A lower side of the control unit 2 is exposed and left uncovered by the top tube 1. A top side of the control unit engages, preferably under bias, to an inner side of a wall of the top tube 1. This engagement typically stabilizes the control unit 2 within the top tube 1. Moreover, this engagement is realized to transfer heat generated by the control unit 2 into the top tube 1. The top tube 1 typically further release at least a part of this heat energy to the surrounding atmosphere. The top tube 1 is preferably at least partially composed of thermally conductive material, such as carbon and/or metal, in particular aluminium. As also shown in FIGS. 3-5, the control unit 2 comprises a heat sink 3 formed by elongated profiled strip with upwardly protruding (elongated) contact portions 3a configured to directly or indirectly co-act with the top tube 1. Preferably, a top side of the contact portions 3a has a substantially complementary shape to the shape of the inner side of the wall of the top tube 1. Preferably, a top side of the contact portions 3a is at least partially substantially convexedly shaped.

Each the contact portions 3a is provided with at least one thermally conductive interface 4 formed by a thermally conductive layer. The layer may e.g. be film and/or a coating. Preferably, the interfaces 4 are at least partially composed of a resilient material. Preferably, the interfaces 4 are electrically insulating and thermally conductive. Examples of suitable materials have been described in the above description. Such a material is configured to adapt its shape to the inner side of the wall of the top tube 1, which secures an intense contact between the interfaces 4 and the top tube 1. The control unit comprises a casing 5 with openings for the contact portions 3a of the heat sink. The casing 5 encloses electronic components mounted on one or more printed circuit boards (PCBs) 9. Some electronic components, such as processors, transistors, MOSFETs, capacitators, will generate heat during normal operation. This heat, or at least a part thereof, can be dissipated via the heat sink 3 via the interfaces 4 to the top tube 1 and normally eventually to the environment. It is imaginable, and may even be preferable, that the heat sink is, directly or indirectly, connecting one or more heat generating components. It is imaginable that, typically a lower side of, the heat sink is provided with at least one thermally conductive, electrically insulating, preferably resilient, interface 6 which engages, preferably under bias, to at least one heat generating component. Optionally, the interfaces 6 are applied onto downwardly protruding contact portions 3b of the heat sink 6. The material of these interfaces 6 may be identical or comparable to the material of the interfaces 4 positioned on top of the heat sink 3. Preferably, a sealing ring 7, preferably made of an elastomer, such as rubber, is provided in between the casing 5 and the heat sink 3. The sealing ring 7 is preferably attached, preferably adhered, onto the heat sink. The heat sink 3 is secured to the casing 5 by means of screws 8. Preferably, the control unit 2 is substantially watertight. The control unit shown in the figures can be configured (and programmed) to control e.g. one or more other control units of the bicycle, at least one electromotor to drive at least one bicycle wheel, lights, and/or one or more other electronic components of the bicycle.

FIG. 6 shows a schematic overview of a bicycle 200 according to the invention. The bicycle 200 comprises a frame comprising a top tube 203, a seat tube 205, a bottom tube 206, a pair of seat stays 216, and a pair of chain stays 218. At the rear axis 219 a rear wheel 208 is rotatably arranged. The rear wheel may be powered by a used via a crank set 221. In order to drive de bicycle 200, the front side of the bicycle may comprise a handlebar 201, which may be rotatable with respect to the head tube 202 of the bicycle. The handlebar 201 may rotate the front wheel 207 which is arranged rotatably on a front axis 220. Said front wheel 207 may be held into place by means of the fork 217 which is rotatably coupled to the handlebar 201 of the bicycle 200. The handlebar 201 may be provided with a brake system 213 for allowing a user to apply a braking force. The handlebar 201 may comprise a first control unit 100, preferably arranged in a stem of the bicycle. Said first control unit may allow the accessory cables of the electronic accessories of the handlebar to be routed at least partially, preferably substantially entirely inside the frame of the bicycle 200. The first control unit 100 allows to reduce the amount of cables running through a steerer tube. One or more optical feedback units 214 may be arranged on and/or in the handlebar 201 for providing the user with optical feedback related to a bicycle status. Inside the bottom tube 206 a primary battery may be arranged for driving at least one electric motor which is arranged in the front axis 220 and/or rear axis 219. Optionally, a secondary battery 222 may be provided for extending the range of the bicycle 200. The primary battery inside the bottom tube 206 and/or the secondary battery 222 may be charged via a charging port 210 of the bicycle 200. The charging port 210 is arranged on a rear side of the bicycle in order to be easily accessible for a user. In this particular embodiment, the charging port 210 is arranged between the pair of seat stays 216 and attached to the seat tube 205 of the bicycle 200. In order for easily connecting the bicycle 200 to an external service device a service port 215 may be provided. In this embodiment the service port 215 is provided on a bottom side of the top tube 203 of the bicycle. Inside the top tube 203 at least one bicycle control unit may be provided. It is imaginable that at least one exposed exterior surface of at least one frame part comprises at least one antenna system. Said antenna system may be directly or indirectly mounted to said bicycle frame 203, 205, 206, 212, 216. The seat tube 205 further accommodates the seat post which may be attached to the saddle 204 of the bicycle 200. In order to increase the visibility of the user of the bicycle 200 during the evening or in the night time, the bicycle 200 may be provided with a front light module 212 and/or a rear light module 211. Said front light module 212 and rear light module 211 may allow for dynamic light patterns and/or for emitting light in at least a left and/or right direction. The bicycle 200 as shown in this figure is merely illustrative for the components thereof. It is explicitly noted that some aspects of the bicycle 200 as shown in this figure may be chosen by way of design. In particular shapes of the light modules 212, 211 may at least partially be shaped by design. Moreover, the shape of the tubes 202, 203, 205, 206 of the bicycle may also at least partially be chosen by way of design. Hence, the aesthetical appearance of the depicted embodiment are matters of design choice and can be varied or eliminated as desired.

The above-described inventive concepts are illustrated by several illustrative embodiments. It is conceivable that individual inventive concepts, including inventive details, may be applied without, in so doing, also applying other details of the described example. It is not necessary to elaborate on examples of all conceivable combinations of the above-described inventive concepts, as a person skilled in the art will understand numerous inventive concepts can be (re) combined in order to arrive at a specific application and/or alternative embodiment.

The ordinal numbers used in this document, like “first”, “second”, and “third” are used only for identification purposes. Hence, the use of expressions like a “second” component, does therefore not necessarily require the co-presence of a “first” component. By “complementary” components is meant that these components are configured to co-act with each other. However, to this end, these components do not necessarily have to have complementary forms. The verb “comprise” and conjugations thereof used in this patent publication are understood to mean not only “comprise”, but are also understood to mean the phrases “contain”, “substantially consist of”, “formed by” and conjugations thereof.

It will be apparent that the invention is not limited to the working examples shown and described herein, but that numerous variants are possible within the scope of the attached claims that will be obvious to a person skilled in the art. The aesthetical appearance and design of the working examples or details thereof, in particular as shown in the appended figures, is not technically determined, unless indicated otherwise, and is merely incorporate to demonstrate and clarify the inventive concept(s) described herein. Hence, the aesthetical appearance of the depicted embodiments are matters of design choice and can be varied or eliminated as desired. The owner of this patent document does moreover not disclaim any other rights that may be lawfully associated with the information disclosed in this document, including but not limited to, copyrights and designs associated with, based upon, and/or derived from the appended figures.

1. An electric bicycle, comprising:
a bicycle frame, and
at least one control unit and/or at least one bicycle device at least partially accommodated within said bicycle frame, wherein said control unit and/or said bicycle device comprises:
at least one heat generating component, and
at least one heat sink thermally co-acting with said at least one heat generating component configured to dissipate heat away from said heat generating component,
wherein said at least one heat sink connects, directly or indirectly, to an inner side of a wall of said bicycle frame such that heat originating from said at least one heat generating component is dissipated at least partially via said at least one heat sink into said wall of said bicycle frame, and wherein said control unit and/or said bicycle device comprises at least one thermally conductive interface attached, directly or indirectly, to at least one heat sink, and interposed in between at least a part of said heat sink and said bicycle frame wall to provide a thermally conductive pathway therebetween, wherein a distant side of the thermally conductive interface, facing away from the at least one heat sink, has a substantially smooth surface, and wherein said distant side of said thermally conductive interface is in substantially continuous physical contact with the inner side of said bicycle frame wall.

2. The electric bicycle according to claim 1, wherein said wall of said bicycle frame is configured to act as heat absorption surface and/or as heat transfer surface and/or wherein said wall of said bicycle frame is at least partially composed of conductive material.

3. (canceled)

4. (canceled)

5. The electric bicycle according to claim 1, wherein said control unit and/or said bicycle device comprises a plurality of thermally conductive interfaces; attached, directly or indirectly, to at least one heat sink, and interposed in between at least a part of said heat sink and said bicycle frame wall to provide a thermally conductive pathway therebetween wherein the plurality of thermally conductive interfaces are arranged in a linear array or matrix array, and wherein at least two of the plurality of thermally conductive interfaces are arranged at a distance from each other.

6. (canceled)

7. The electric bicycle according to claim 1, wherein at least one heat sink is fastened to said at least one heat generating component by at least one mechanical fastening element.

8. The electric bicycle according to claim 4, wherein the at least one screw used to fasten said at least one heat sink to said at least one heat generating component, comprises a screw head, wherein said screw head engages a side of the heat sink facing away of the heat generating component, wherein the screw head of said at least one screw is accommodated in a recessed portion of the heat sink.

9. (canceled)

10. (canceled)

11. The electric bicycle according to claim 1, wherein the length of the heat sink is larger, than the length of an individual thermally conductive interface and/or wherein at least one thermally conductive interface directly connects to the bicycle frame wall and/or wherein at least one thermally conductive interface is at least partially composed of a compressible material.

12. (canceled)

13. (canceled)

14. The electric bicycle according to claim 1, wherein at least one thermally conductive interface is at least partially composed of at least one polymer.

15. The electric bicycle according to claim 7, wherein at least one filler is dispersed in the polymer and/or wherein at least one thermally conductive interface is at least partially composed of at least one thermoplastic polyurethane.

16. (canceled)

17. The electric bicycle according to claim 1 wherein the thermally conductive interface is an electrically insulating, thermally conductive interface and/or wherein the thermal conductivity of the thermally conductive interface increases as pressure on the thermally conductive interface increases.

18. (canceled)

19. (canceled)

20. The electric bicycle according to claim 1, wherein at least one thermally conductive interface comprises a first surface, composed of a first pressure sensitive adhesive (PSA), bonded to the heat sink, and an opposing second surface, composed of a second pressure sensitive adhesive (PSA), bonded to the inner surface of the wall of the bicycle frame.

21. The electric bicycle according to claim 10, wherein the first PSA and/or second PSA comprises a silicone pressure sensitive adhesive component and/or wherein said first PSA and/or second PSA comprises a blend of an acrylic pressure sensitive adhesive component and a second thermally-conductive filler, wherein said first PSA comprises between 0% and about 15% by weight of said first thermally-conductive filler, and wherein said second PSA comprises between about 15% and about 85% by weight of said second thermally conductive filler, wherein said first and said second thermally-conductive filler are selected from the group consisting of: boron nitride, titanium diboride, aluminium oxide, aluminium nitride, magnesium oxide, zinc oxide, silicon carbide, beryllium oxide, antimony oxide, and mixtures thereof.

22. (canceled)

23. (canceled)

24. The electric bicycle according to claim 1, wherein at least one thermally conductive interface comprises a phase change material (PCM).

25. The electric bicycle according to claim 1, wherein the heat sink comprises a thermally conductive block or strip covering at least a part of the at least one heat generating component, wherein said block or strip is at least partially composed of metal and/or wherein the control unit and/or said bicycle device comprises an outer casing, and wherein the heat sink comprises a sealing element to seal a space in between said outer casing and said heat sink.

26. (canceled)

27. (canceled)

28. The electric bicycle according to claim 1, wherein the control unit and/or the bicycle device is substantially watertight and/or wherein the control unit and/or the bicycle device is mounted to the bicycle frame by means of at least one fastening element and/or wherein the bicycle frame comprises a top tube, wherein the control unit is mounted to said top tube and at least partially accommodated within said top tube.

29-32. (canceled)

33. The electric bicycle according to claim 1, wherein the control unit and/or the bicycle device comprises at least one printed circuit board (PCB), and wherein at least one heat generating component is mounted onto said PCB.

34. The electric bicycle according to claim 1, wherein at least one control unit forms a main ECU (electronic control unit) and/or wherein at least one heat generating component is chosen from the group consisting of: a capacitor, a battery, a connector, a semiconductor chip, a processor, and a metal-oxide-silicon field effect transistor (MOSFET).

35. (canceled)

36. The electric bicycle according to claim 1, wherein the bicycle comprises foot pedals, wherein said pedals are, directly or indirectly, connected to a crank set of the bicycle for propelling the bicycle and/or wherein the bicycle is a pedal operable electric bicycle and/or wherein the bicycle comprises at least one electromotor to drive at least one wheel of the bicycle.

37. (canceled)

38. (canceled)

39. The electric bicycle according to claim 1, wherein the bicycle comprises a pedal-operated manpower driven system and an electromotor driven system in parallel to each other, wherein at least one bicycle control unit is configured to control the output of the electromotor driven in response to a pedal depressing force of the manpower driven system.

40. A control unit and/or bicycle device for use in a bicycle according to claim 1, wherein the control unit and/or the bicycle device comprises:
at least one heat generating component, and
at least one heat sink configured to thermally co-act with said at least one heat generating component configured to dissipate heat away from said heat generating component,
wherein said at least one heat sink is configured to connect, directly or indirectly, to an inner side of a wall of said bicycle frame such that heat originating from said at least one heat generating component will be dissipated via said at least one heat sink into said wall of said bicycle frame.
